(19) United States
(12) Patent Application Publication
(10) Pub. No.: US 2025/0118551 A1
(43) Pub. Date: Apr. 10, 2025

(54) SEED CRYSTAL SUBSTRATE AND GRAPHITE SUSCEPTOR WITH SEED CRYSTAL SUBSTRATE

(71) Applicant: KABUSHIKI KAISHA TOYOTA CHUO KENKYUSHO, Nagakute-shi (JP)

(72) Inventors: Daisuke NAKAMURA, Nagakute-shi (JP); Kenji Itoh, Nagakute-shi (JP)

(73) Assignee: KABUSHIKI KAISHA TOYOTA CHUO KENKYUSHO, Nagakute-shi (JP)

(21) Appl. No.: 18/783,732

(22) Filed: Jul. 25, 2024

(30) Foreign Application Priority Data
Oct. 5, 2023 (JP) 2023-173936

(51) Int. Cl. H01L 21/02

(52) U.S. Cl. CPC H01L 21/02389; H01L 21/0254; H01L 21/02645

(57) ABSTRACT

A seed crystal substrate includes: a substrate having a GaN seed crystal on a front surface thereof; an adhesion layer formed on a back surface of the substrate; and a carbon film covering the adhesion layer. The substrate includes a GaN single crystal substrate or a sapphire substrate with a GaN film, and the adhesion layer contains Si. Thus, a carbon film having a high infrared emissivity is disposed on a back surface side of the seed crystal substrate, and heat dissipation by radiation can be sufficiently secured even under a low pressure condition. Therefore, the controllability of the substrate surface temperature can be enhanced.

### FIELD OF THE INVENTION

The present invention relates to a seed crystal substrate and a graphite susceptor with a seed crystal substrate, and more particularly to a seed crystal substrate having a GaN seed crystal on a surface thereof and a graphite susceptor with a seed crystal substrate having a GaN seed crystal on a surface thereof.

### BACKGROUND OF THE INVENTION

Conventionally, gallium nitride (GaN) has been widely used mainly in optical devices such as LEDs and lasers. In addition, GaN is a wide gap semiconductor (band gap: 3.39 eV), has high dielectric field breakdown strength, can thin a drift layer, and can reduce on-resistance, and therefore is expected to be applied not only to optical devices but also to power devices.

Several techniques are known for crystal growth of GaN. For example, a molecular beam epitaxy (MBE) method or a metal organic chemical vapor deposition (MOVPE) method is used in crystal growth up to a relatively small film thickness of about several micrometers. On the other hand, a hydride vapor phase epitaxy (HVPE) method is used in crystal growth of a free-standing substrate having a film thickness exceeding 10 μm.

Although the HVPE method has a high crystal growth rate (≈100 μm/h) and is suitable for producing a free-standing substrate, O impurities are inevitably mixed into growing crystal due to auto-doping from quartz as a reaction vessel. Since the O impurities act as a donor in the GaN crystal, there is a problem in quality of the GaN single crystal.

Therefore, a halogen-free vapor phase epitaxy (HF-VPE) method described in Non-Patent Literature 1 has been proposed as a crystal growth method for producing a high-quality, large-diameter, and low-cost GaN free-standing substrate.

Non-Patent Literature 1 discloses:
(1) a crucible that holds molten Ga and is kept at a high temperature;
(2) an NH₃ gas supply source; and
(3) a seed crystal substrate having a GaN seed crystal on a surface thereof and facing the crucible.

Non-Patent Literature 1 discloses that the HF-VPE method has a high crystal growth rate (>100 μm/h) and also high stability of the crystal growth rate.

However, in the HF-VPE method in Non-Patent Literature 1, crystal growth is performed under a low pressure condition (<10 kPa) and thus cannot rely on heat conduction of a gas, which results in delayed heat dissipation of the substrate in some cases. This is due to a significantly small (ε=0.2 to 0.4) infrared emissivity ε on a back surface side of the substrate when the substrate is a GaN single crystal substrate or a sapphire substrate with a GaN film. That is, under a situation where the heat dissipation of the substrate must rely on radiation, the substrate is likely to be excessively stuffed with heat due to its low infrared emissivity E.

For this reason, the substrate may be overheated and may not have a stable substrate surface temperature.

Therefore, a countermeasure is conceivable in which the seed crystal substrate is brought into contact with another member such as a graphite susceptor and thermally conducted to the other member to dissipate heat, but a sufficient heat dissipation effect cannot be obtained by simply bringing the seed crystal substrate into contact with the other member under a low pressure condition.

Since the fluctuation in substrate surface temperature inhibits the crystal growth rate and the stability of the crystal growth rate, it is necessary to further improve control of the substrate surface temperature.

Therefore, various proposals as will be described below have been made.

Patent Literature 1 discloses:
a support with a seed crystal substrate, including:
(1) an SiC substrate having a seed crystal on a front surface thereof;
(2) a carbon film formed on a back surface of the SiC substrate; and
(3) a carbon fixing layer derived from a carbon-based adhesive, the layer being interposed and inserted between the carbon film and a support disposed on a back surface side of the carbon film to fix the SiC substrate to the support.

Patent Literature 2 discloses:
a support with a seed crystal substrate, including:
(1) an SiC substrate having a seed crystal on a front surface thereof; and
(2) an SiC fixing layer derived from a polycarbosilane-based adhesive, the layer being interposed and inserted between a back surface of the SiC substrate and a support to fix the SiC substrate to the support.

There may be an opinion that the substrate of Non-Patent Literature 1 and another member are joined with the carbon-based adhesive described in Patent Literature 1, thereby making it possible to improve heat dissipation of the substrate. However, the substrate having a GaN seed crystal on a surface thereof is generally a sapphire substrate or a GaN single crystal substrate, but both the substrates have very poor adhesion to the carbon film. The same applies to the carbon-based adhesive, and it is difficult to join the sapphire substrate and the GaN single crystal substrate to another member with the carbon-based adhesive.

On the other hand, the sapphire substrate and the GaN single crystal substrate can be joined to another member by using the polycarbosilane-based adhesive of Patent Literature 2.

However, the polycarbosilane-based adhesive generates Si-containing gas molecular species during growth of GaN single crystals, which attach to GaN seed crystal surfaces as Si impurities and inhibit growth of high-quality GaN single crystals.

### CITATION LIST

### Patent Literature

Patent Literature 1: JP 2013-124196 A
Patent Literature 2: JP 2013-237592 A

### Non-Patent Literature

Non-Patent Literature 1: Nakamura, D.; Kimura, T.; Horibuchi, K., Halogen-free vapor phase epitaxy for high-rate growth of GaN bulk crystals, Appl. Phys. Express 2017, 10(4), 045504

### SUMMARY OF THE INVENTION

An object of the present invention is to provide a seed crystal substrate having high controllability of a substrate surface temperature.

Another object of the present invention is to provide a graphite susceptor with a seed crystal substrate having high controllability of a substrate surface temperature.

In order to attain the above objects, a seed crystal substrate according to a first embodiment includes:
a substrate having a GaN seed crystal on a front surface thereof; an adhesion layer formed on a back surface of the substrate; and a carbon film covering the adhesion layer.

The substrate includes a GaN single crystal substrate or a sapphire substrate with a GaN film.

The adhesion layer contains Si.

A seed crystal substrate according to a second embodiment further includes:
an expanded graphite sheet disposed on a back surface side of the carbon film; and
a joining layer that joins the carbon film and the expanded graphite sheet.

A graphite susceptor with the seed crystal substrate according to the first embodiment includes:
the seed crystal substrate according to the first embodiment;
a graphite susceptor disposed on a back surface side of the seed crystal substrate; and
a fixing layer that fixes the seed crystal substrate to the graphite susceptor.

An absolute value of a difference in average coefficient of thermal expansion between the substrate and the graphite susceptor is 0.5×10⁻⁶ K⁻¹ or less.

A graphite susceptor with the seed crystal substrate according to the second embodiment includes:
the seed crystal substrate according to the second embodiment;
a graphite susceptor disposed on a back surface side of the seed crystal substrate; and
a fixing layer that fixes the seed crystal substrate to the graphite susceptor.

In the graphite susceptor with the seed crystal substrate according to the second embodiment, an absolute value of a difference in average coefficient of thermal expansion between the substrate and the graphite susceptor is preferably 0.5×10⁻⁶ K⁻¹ or less.

### [Seed Crystal Substrate]

In the seed crystal substrate according to the present invention, an Si film as an adhesion layer is formed on a back surface of a substrate, and a carbon film is formed so as to cover the Si film. The Si film has good adhesion to a GaN single crystal substrate and a sapphire substrate, and also has good adhesion to a carbon film.

That is, a carbon film having a high infrared emissivity (ε=0.7 to 0.9) is formed on a back surface side of the seed crystal substrate, and heat dissipation by radiation can be sufficiently secured even under a low pressure condition.

Therefore, controllability of a substrate surface temperature can be enhanced.

In the seed crystal substrate, the carbon film having good thermal conductivity is disposed on the back surface side, and thus occurrence of temperature unevenness in a plane of the seed crystal substrate can also be suppressed. Therefore, the controllability of the substrate surface temperature can be further enhanced.

[Graphite Susceptor with Seed Crystal Substrate]

The graphite susceptor with a seed crystal substrate according to the present invention is obtained by fixing the seed crystal substrate according to the present invention to a graphite susceptor disposed on a back surface side thereof via a fixing layer.

As a result, heat dissipation of the substrate can be performed by direct heat conduction due to joining of the seed crystal substrate and the graphite susceptor.

Therefore, the controllability of the substrate surface temperature can be enhanced.

### BRIEF DESCRIPTION OF THE DRAWINGS

FIG. 1 is a schematic cross-sectional view of a seed crystal substrate (first embodiment);

FIG. 2 is a schematic cross-sectional view of a seed crystal substrate (second embodiment);

FIG. 3 is a schematic cross-sectional view of a graphite susceptor with a seed crystal substrate (first embodiment);

FIG. 4 is a schematic cross-sectional view of a graphite susceptor with a seed crystal substrate (second embodiment);

FIG. 5 is a schematic cross-sectional view of a graphite susceptor with a seed crystal substrate (Comparative Example); and

FIG. 6 is a view illustrating a correlation between a joint state and a thickness of an adhesion layer.

### DETAILED DESCRIPTION OF PREFERRED EMBODIMENTS

### [Configuration 1]

A seed crystal substrate including:
a substrate having a GaN seed crystal on a front surface thereof;
an adhesion layer formed on a back surface of the substrate; and
a carbon film covering the adhesion layer,
wherein
the substrate includes a GaN single crystal substrate or a sapphire substrate with a GaN film, and
the adhesion layer contains Si.

### [Configuration 2]

The seed crystal substrate according to Configuration 1, wherein the adhesion layer has a thickness of 10 nm or more and 200 nm or less.

### [Configuration 3]

The seed crystal substrate according to Configuration 1 or 2, wherein the carbon film has a thickness of 5 nm or more and 100 nm or less.

### [Configuration 4]

The seed crystal substrate according to any one of Configurations 1 to 3, further including:
an expanded graphite sheet disposed on a back surface side of the carbon film; and
a joining layer that joins the carbon film and the expanded graphite sheet.

### [Configuration 5]

The seed crystal substrate according to Configuration 4, wherein the joining layer includes:
graphite particles; and
a carbon layer interposed between the graphite particles.

### [Configuration 6]

A graphite susceptor with a seed crystal substrate, including:
the seed crystal substrate according to any one of Configurations 1 to 3;
a graphite susceptor disposed on a back surface side of the seed crystal substrate; and
a fixing layer that fixes the seed crystal substrate to the graphite susceptor,
wherein an absolute value of a difference in average coefficient of thermal expansion between the substrate and the graphite susceptor is 0.5×10⁻⁶ K⁻¹ or less.

### [Configuration 7]

The graphite susceptor with a seed crystal substrate according to Configuration 6, wherein the fixing layer includes:
graphite particles; and
a carbon layer interposed between the graphite particles.

### [Configuration 8]

A graphite susceptor with a seed crystal substrate, including:
the seed crystal substrate according to Configuration 4 or 5;
a graphite susceptor disposed on a back surface side of the seed crystal substrate; and
a fixing layer that fixes the seed crystal substrate to the graphite susceptor.

### [Configuration 9]

The graphite susceptor with a seed crystal substrate according to Configuration 8, wherein an absolute value of a difference in average coefficient of thermal expansion between the substrate and the graphite susceptor is 0.5×10⁻⁶ K⁻¹ or less.

### [Configuration 10]

The graphite susceptor with a seed crystal substrate according to Configuration 8 or 9, wherein the fixing layer includes:
graphite particles; and
a carbon layer interposed between the graphite particles.

Hereinafter, embodiments of the present invention will be described in detail.

### [1. Seed Crystal Substrate]

A seed crystal substrate according to the present invention includes:
a substrate having a GaN seed crystal on a front surface thereof;
an adhesion layer formed on a back surface of the substrate; and
a carbon film covering the adhesion layer.

The substrate includes a GaN single crystal substrate or a sapphire substrate with a GaN film, and the adhesion layer contains Si.

The seed crystal substrate according to the present invention may further include:
an expanded graphite sheet disposed on a back surface side of the carbon film; and
a joining layer that joins the carbon film and the expanded graphite sheet.

### [1.1 Substrate]

The substrate has a GaN seed crystal on a front surface thereof, and is a GaN single crystal substrate or a sapphire substrate with a GaN film.

Here, a plane orientation of a surface of the GaN seed crystal is not particularly limited, and may be a (0001) plane (Ga plane) or (000-1) plane (N plane) which is a polar plane, a (11-20) plane (a plane) or (10-10) plane (m plane) which is a nonpolar plane, or a (01-12) plane (r plane) which is a semipolar plane.

For example, the plane orientation of the surface of the GaN seed crystal is preferably a (0001) plane in which impurities are taken in a relatively small amount during growth of a GaN single crystal and a high-quality GaN single crystal can be obtained.

### [1.1.1. GaN Single Crystal Substrate]

The GaN single crystal substrate preferably has a front surface subjected to a chemical mechanical polishing (CMP) treatment and a back surface subjected to a lapping polishing treatment.

[1.1.2. Sapphire Substrate with GaN Film]

The sapphire substrate with a GaN film is preferably one in which a heteroepitaxial GaN film (0001) plane formed on a sapphire substrate having a (0001) plane or (11-20) plane as a front surface is formed with a film thickness of 1 to 2 μm by an MOVPE method.

Furthermore, the sapphire substrate with a GaN film is preferably subjected to a lapping polishing treatment on the back surface.

### [1.2. Adhesion Layer]

A certain adhesion layer is required between the substrate and a carbon film which will be described later. This is because the adhesion of the carbon film to the GaN single crystal substrate and the sapphire substrate is very poor, as described above. Therefore, the material for the adhesion layer needs to have adhesion to the carbon film in addition to adhesion to the GaN single crystal substrate or the sapphire substrate. Examples of such a material include Si.

As a method of forming an Si film as the adhesion layer, an electron-beam physical vapor deposition method, a sputtering vapor deposition method, a chemical vapor deposition (CVD) method, a pulsed laser deposition (PLD) method, or the like is conceivable.

The obtained Si film may be an amorphous film or a single crystal film.

Therefore, as the Si film, an amorphous Si film obtained by an electron-beam physical vapor deposition method or a sputtering vapor deposition method is suitably used.

In addition, when the film thickness of the Si film is too thin, film peeling due to a chemical reaction with the carbon film will be described later is concerned. Therefore, the film thickness of the Si adhesion layer is preferably 10 nm or more, and more preferably 15 nm or more, 20 nm or more, or 25 nm or more.

On the other hand, too large a film thickness of the Si film results in concerns about an increase in film formation cost and film peeling due to an increase in film stress. Therefore, the film thickness of the Si film is preferably 200 nm or less, and more preferably 150 nm or less, or 100 nm or less.

Here, it may be pointed out that the Si film may generate Si which may have an adverse influence during growth of the GaN single crystal, similarly to the above-described polycarbosilane-based adhesive, but there is no problem because it is considered that the Si film forms passivated SiC with the carbon film which will be described later during the growth of the GaN single crystal.

That is, it is considered that Si and SiC are mixedly present in the adhesion layer after the growth of the GaN single crystal.

### [1.3. Carbon Film]

The carbon film dissipates heat by radiation as described above, and contributes to improvement of the controllability of the substrate surface temperature.

As a method of forming the carbon film, a carbonization (heat) treatment of a spin-coated film of a photoresist, a sputtering vapor deposition method, a CVD method, a PLD method, and the like are conceivable.

The obtained carbon film may be an amorphous film or a single crystal film. Here, the single crystal carbon film is, for example, a laminate of graphene, and is formed by a CVD method or the like.

Therefore, as the carbon film, an amorphous carbon film obtained by subjecting a spin-coated film of a photoresist to a carbonization treatment is suitably used.

As the photoresist, a phenol resin solution, a novolak resin solution, and the like can be used.

Specifically, first, a photoresist is dropped onto an Si film which serves as an adhesion layer on a back surface of a substrate, and a rotation treatment is performed at a rotation rate of 1000 to 5000 rpm for a time of 30 seconds to form a spin-coated film of 0.5 to 10 μm.

Next, the substrate with the spin-coated film is subjected to a heat treatment at a temperature of 800° C. for a time of 1 hour in a vacuum or inert gas atmosphere to form a carbon film covering the Si film on the back surface of the substrate.

Too small a film thickness of the carbon film results in a concern about a decrease in infrared emissivity. Therefore, the film thickness of the carbon film is preferably 5 nm or more, and more preferably 10 nm or more, or 15 nm or more.

On the other hand, too large a film thickness of the carbon film results in a concern about film peeling due to an increase in film stress. Therefore, the film thickness of the carbon film is preferably 100 nm or less, and more preferably 50 nm or less, or 20 nm or less.

### [1.4. Expanded Graphite Sheet]

The expanded graphite sheet has excellent workability and flexibility, and thus is a graphite sheet that is very easy to handle.

The expanded graphite sheet is not necessarily required. However, the heat dissipation by radiation of the substrate can be further improved by further disposing the expanded graphite sheet on the back surface side of the substrate.

In addition, in the case where the expanded graphite sheet is interposed and inserted between the substrate and a graphite susceptor which will be described later, the expanded graphite sheet functions as a stress buffer layer due to its flexibility.

Too small a thickness of the expanded graphite sheet makes handling difficult, resulting in a possibility that the expanded graphite sheet may not function when used as the stress buffer layer. Therefore, the thickness of the expanded graphite sheet is preferably 10 μm or more, and more preferably 50 μm or more.

On the other hand, too large a thickness of the expanded graphite sheet results in a possibility that heat dissipation may rather be hindered. Therefore, the thickness of the expanded graphite sheet is preferably 500 μm or less, and more preferably 200 μm or less.

### [1.5. Joining Layer]

The joining layer joins the carbon film and the expanded graphite sheet.

The joining layer is derived from a carbon-based adhesive generally used in adhesion of a graphite material, and is composed of graphite particles and a carbon layer interposed between the graphite particles.

The carbon-based adhesive is a mixture including a carbon-based resin, graphite particles, a polymerization accelerator, a solvent, and the like.

The graphite particles are used as fillers, but the particle size, the content, and the like are not particularly limited, and optimum ones may be appropriately selected according to the purpose. The particle size of the graphite particles is preferably 0.3 μm or more and 10 μm or less. The content of the graphite particles is preferably 10 mass % or more and 60 mass % or less.

As the carbon-based adhesive, a phenol resin-based adhesive, a novolac resin-based adhesive, a furfuryl alcohol resin-based adhesive, and the like can be used.

Specifically, first, the carbon film and the expanded graphite sheet are adhered with a carbon-based adhesive, and heated at a temperature of 200° C. for a time of 20 minutes in the atmospheric air to cure the carbon-based adhesive.

The application method of the carbon-based adhesive and the pressure bonding force are adjusted so as to attain a thickness of the adhesive layer ranging from several micrometers to ten and several micrometers.

Next, the substrate to which the expanded graphite sheet is adhered via the carbon-based adhesive layer is subjected to a heat treatment at a temperature of 800° C. for a time of 1 hour in a vacuum or an inert gas atmosphere to perform a carbonization treatment on the adhesive layer, thereby forming a joining layer.

Here, the carbon-based adhesive includes a carbon-based resin that becomes non-graphitizable carbon by a carbonization treatment, and the joining layer formed by the carbonization treatment of the carbon-based adhesive includes graphite particles and non-graphitizable carbon interposed between the graphite particles.

In the carbonization treatment, an oxygen-containing gas such as moisture is released from a solvent or the like of the carbon-based adhesive, and thus the carbon film also has a function as an antioxidant film for the Si film. Also from this viewpoint, the film thickness of the carbon film is required to be at least 5 nm or more.

In the absence of a carbon film, the Si film is oxidized during the carbonization treatment, so that peeling occurs at an interface with the oxidized Si film.

The seed crystal substrate may be used in, for example, an atmospheric pressure MOVPE apparatus. In this case, it is considered that thermal conduction by contact with the susceptor is sufficient for the seed crystal substrate. Since absorption rate is equal to radiation rate, it is considered that the absorption rate of the seed crystal substrate is also improved by the carbon film or the like on the back surface.

Therefore, for example, even when temperature modulation is applied to the susceptor, the substrate surface temperature can be controlled with good followability.

This makes it possible to further improve controllability of InGaN and AlGaN layers in which intake of In and Al changes depending on the temperature.

### 1.6. Specific Examples

### 1.6.1. Specific Example 1

FIG. 1 shows a schematic cross-sectional view of a seed crystal substrate according to a first embodiment of the present invention.

A seed crystal substrate 1 includes:
a substrate 2 having a GaN seed crystal on a surface thereof;
an adhesion layer 3 formed on a back surface of the substrate 2; and
a carbon film 5 covering the adhesion layer 3.

The substrate 2 is a GaN single crystal substrate or a sapphire substrate with a GaN film.

In addition, the adhesion layer 3 contains Si.

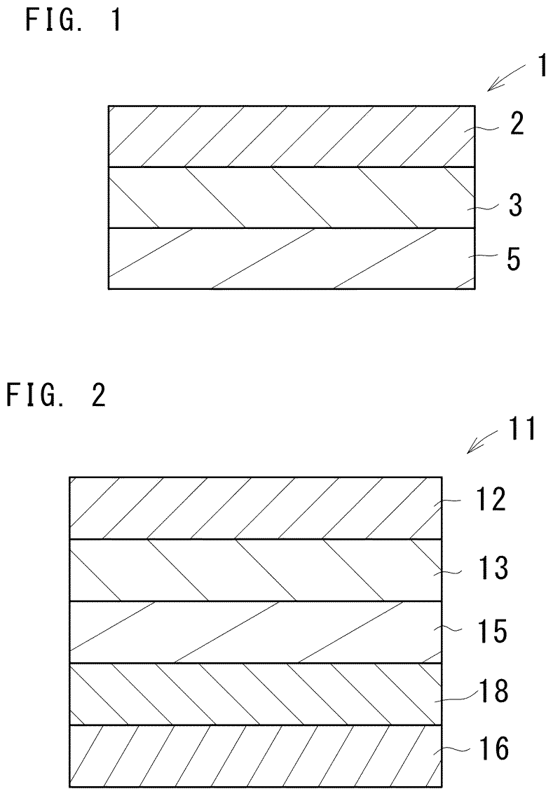

In FIG. 1, the dimensions of each part are enlarged or reduced as compared with the actual dimensions for easy viewing. The same applies to FIGS. 2 to 5.

### 1.6.2. Specific Example 2

FIG. 2 shows a schematic cross-sectional view of a seed crystal substrate according to a second embodiment of the present invention.

A seed crystal substrate 11 includes:
a substrate 12 having a GaN seed crystal on a surface thereof;
an adhesion layer 13 formed on a back surface of the substrate 12; and
a carbon film 15 covering the adhesion layer 13.

The substrate 12 is a GaN single crystal substrate or a sapphire substrate with a GaN film.

In addition, the adhesion layer 13 contains Si.

The seed crystal substrate 11 further includes:
an expanded graphite sheet 16 disposed on a back surface side of the carbon film 15; and
a joining layer 18 that joins the carbon film 15 and the expanded graphite sheet 16.

The expanded graphite sheet 16 functions as a radiation enhancement layer.

[2. Graphite Susceptor with Seed Crystal Substrate]

A graphite susceptor with a seed crystal substrate according to the present invention has the following configuration:

A graphite susceptor with a seed crystal substrate, including:
the seed crystal substrate according to the present invention;
a graphite susceptor disposed on a back surface side of the seed crystal substrate; and
a fixing layer that fixes the seed crystal substrate to the graphite susceptor.

### [2.1. Seed Crystal Substrate]

The seed crystal substrate according to the present invention includes:
(a) the seed crystal substrate according to the first embodiment, or
(b) the seed crystal substrate according to the second embodiment.

The details of the seed crystal substrates are as described above, and thus the detailed descriptions thereof will be omitted.

### [2.2. Graphite Susceptor]

Graphite has high chemical resistance and high-temperature resistance, and is generally used as a member for high temperatures. Examples of the graphite include isotropic graphite having a small coefficient of thermal expansion aligned in all directions, and extruded graphite formed by extrusion molding.

Since the growth of the GaN single crystal by an HF-VPE method is a crystal growth in a high temperature range where the substrate surface temperature is about 1100° C., a graphite susceptor is used as the susceptor. As the graphite susceptor, a graphite susceptor made of isotropic graphite is preferably used.

The “isotropic graphite” refers to a polycrystalline graphite material produced by cold isostatic press (CIP) method. The graphite belongs to a hexagonal system, and therefore has anisotropy in characteristics. On the other hand, the isotropic graphite is characterized by having no characteristic difference due to a difference in cutting direction since each crystal grain is non-oriented in crystal orientation.

Here, in the HF-VPE method, the graphite susceptor is a seed crystal substrate holder that holds the seed crystal substrate, is a material to be heated that receives energy from a heating source, and also serves as a heat dissipation material that dissipates heat received from a high-temperature crucible (≈1250° C.).

Therefore, the seed crystal substrate is fixed to the graphite susceptor by a fixing layer which will be described later, thereby making it possible to perform the heat dissipation of the seed crystal substrate via the graphite susceptor, and to enhance the controllability of the substrate surface temperature.

The graphite susceptor may be coated with an SiC film or the like.

This makes it possible to further improve durability of the graphite susceptor even in a high-temperature environment exposed to NH₃ gas.

### [2.3. Fixing Layer]

The fixing layer fixes the seed crystal substrate to the graphite susceptor.

The fixing layer is derived from a carbon-based adhesive generally used in adhesion of a graphite material, and is composed of graphite particles and a carbon layer interposed between the graphite particles.

The details of the fixing layer are the same as those of the above-described joining layer, and thus the descriptions thereof will be omitted.

Note that the fixing layer and the joining layer may be the same or different.

### [2.4. Difference in Average Coefficient of Thermal Expansion]

The average coefficient of thermal expansion (average value of coefficient of thermal expansion (CTE) at from room temperature to 1000° C., hereinafter referred to as average CTE) of the isotropic graphite usually has a value of about 3.8 to 7.0×10⁻⁶ K⁻¹ depending on the manufacture method and composition.

In addition, the average CTE of the sapphire substrate is 7×10⁻⁶ K⁻¹, and the average CTE of the GaN single crystal substrate is 5.5×10⁻⁶ K⁻¹.

Therefore, in the absence of an expanded graphite sheet between the carbon film and the graphite susceptor, the absolute value of the difference in average CTE between the graphite susceptor and the seed crystal substrate needs to be 0.5×10⁻⁶ K⁻¹ or less, in order to prevent the seed crystal substrate from falling off from the graphite susceptor during temperature rise or the like.

For example, in the case of the sapphire substrate, the average CTE of the graphite susceptor needs to be 6.5×10⁻⁶ K⁻¹ to 7.5×10⁻⁶ K⁻¹. In the case of the GaN single crystal substrate, the average CTE of the graphite susceptor needs to be 5.0×10⁻⁶ K⁻¹ to 6.0×10⁻⁶ K⁻¹.

Further, in the case of the sapphire substrate, the average CTE of the graphite susceptor is more preferably 6.8×10⁻⁶ K⁻¹ to 7.3×10⁻⁶ K⁻¹. In the case of the GaN single crystal substrate, the average CTE of the graphite susceptor is more preferably 5.3×10⁻⁶ K⁻¹ to 5.7×10⁻⁶ K⁻¹.

Here, in the seed crystal substrate of the second embodiment, the flexible expanded graphite sheet functions as the stress buffer layer, and thus the absolute value of the difference in average CTE between the seed crystal substrate and the graphite susceptor does not necessarily need to be 0.5×10⁻⁶ K⁻¹ or less. However, even in a case where the expanded graphite sheet is provided, an absolute value of the difference in average CTE of 0.5×10⁻⁶ K⁻¹ or less makes it possible to further suppress a decrease in durability due to thermal stress.

### 2.5. Specific Examples

### 2.5.1. Specific Example 1

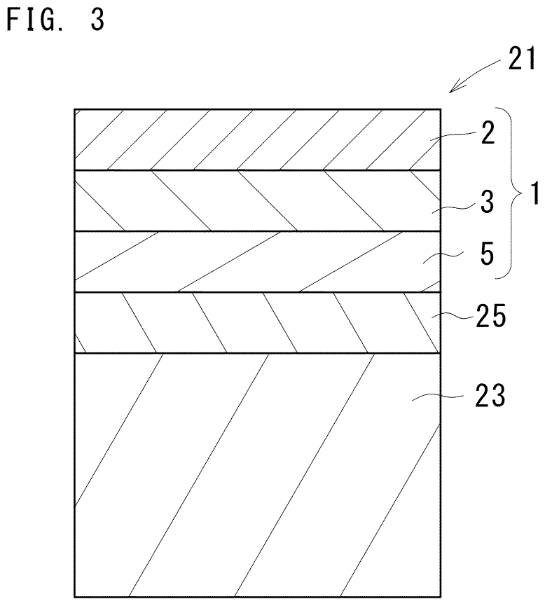

FIG. 3 shows a schematic cross-sectional view of a graphite susceptor with the seed crystal substrate according to the first embodiment of the present invention.

A graphite susceptor 21 with a seed crystal substrate includes:
the seed crystal substrate 1;
a graphite susceptor 23 disposed on a back surface side of the seed crystal substrate 1; and
a fixing layer 25 that fixes the seed crystal substrate 1 to the graphite susceptor 23.

### 2.5.2. Specific Example 2

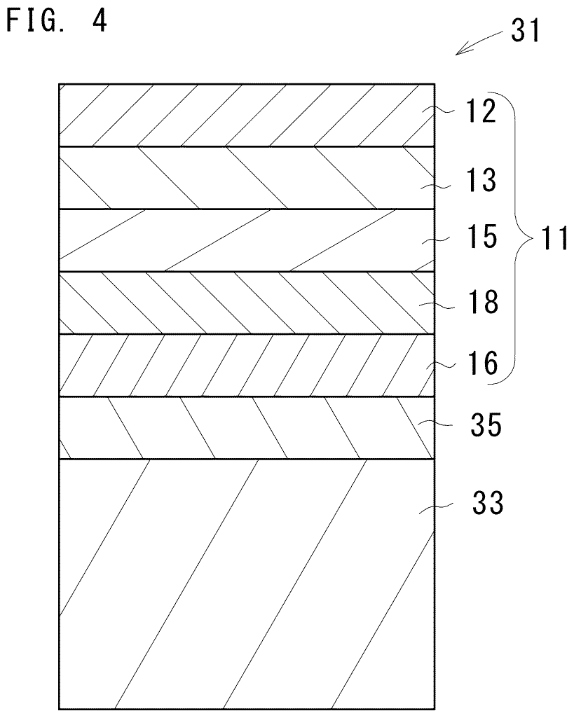

FIG. 4 shows a schematic cross-sectional view of a graphite susceptor with the seed crystal substrate according to the second embodiment of the present invention.

A graphite susceptor 31 with a seed crystal substrate includes:
the seed crystal substrate 11;
a graphite susceptor 33 disposed on a back surface side of the seed crystal substrate 11; and
a fixing layer 35 that fixes the seed crystal substrate 11 to the graphite susceptor 33.

When the seed crystal substrate 11 is used as it is, the expanded graphite sheet functions as the radiation enhancement layer, but in the graphite susceptor 31 with a seed crystal substrate, the expanded graphite sheet 16 functions as the stress buffer layer.

### [3. Action]

### [3.1. Seed Crystal Substrate]

In the seed crystal substrate according to the present invention, an Si film as an adhesion layer is formed on a back surface of a substrate, and a carbon film is formed so as to cover the Si film. The Si film has good adhesion to a GaN single crystal substrate and a sapphire substrate, and also has good adhesion to a carbon film.

That is, a carbon film having a high infrared emissivity (ε=0.7 to 0.9) is formed on a back surface side of the seed crystal substrate, and heat dissipation by radiation can be sufficiently secured even under a low pressure condition.

Therefore, the controllability of the substrate surface temperature can be enhanced.

[3.2. Graphite Susceptor with Seed Crystal Substrate]

The graphite susceptor with a seed crystal substrate according to the present invention is obtained by fixing the seed crystal substrate according to the present invention to a graphite susceptor disposed on a back surface side thereof via a fixing layer.

As a result, heat dissipation of the substrate can be performed by direct heat conduction due to joining of the seed crystal substrate and the graphite susceptor.

Therefore, the controllability of the substrate surface temperature can be enhanced.

### EXAMPLES

### Examples 1 to 3 and Comparative Examples 1 to 3: Seed Crystal Substrate

### [4.1. Preparation of Sample]

### 4.1.1. Example 1

First, a 100 nm-thick Si film (EB-Si) was formed as an adhesion layer on back surfaces of a GaN single crystal substrate and a sapphire substrate with a GaN film by an electron-beam physical vapor deposition method.

Next, a spin-coated film of a photoresist (THMR-IP5700 manufactured by TOKYO OHKA KOGYO CO., LTD.) was formed so as to cover the Si film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the Si film on the back surface of the substrate (see FIG. 1).

### 4.1.2. Example 2

First, a 50 nm-thick Si film (sputter-Si) was formed as an adhesion layer on back surfaces of a GaN single crystal substrate and a sapphire substrate with a GaN film by a sputtering vapor deposition method.

Next, a spin-coated film of a photoresist (THMR-IP5700 manufactured by TOKYO OHKA KOGYO CO., LTD.) was formed so as to cover the Si film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the Si film on the back surface of the substrate (see FIG. 1).

### 4.1.3. Comparative Example 1

First, a 100 nm-thick Ti film (EB-Ti) was formed as an adhesion layer on back surfaces of a GaN single crystal substrate and a sapphire substrate with a GaN film by an electron-beam physical vapor deposition method.

Next, a spin-coated film of a photoresist (THMR-IP5700 manufactured by TOKYO OHKA KOGYO CO., LTD.) was formed so as to cover the Ti film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the Ti film on the back surface of the substrate (see FIG. 1).

### 4.1.4. Comparative Example 2

First, a 100 nm-thick Ni film (EB-Ni) was formed as an adhesion layer on back surfaces of a GaN single crystal substrate and a sapphire substrate with a GaN film by an electron-beam physical vapor deposition method.

Next, a spin-coated film of a photoresist (THMR-IP5700 manufactured by TOKYO OHKA KOGYO CO., LTD.) was formed so as to cover the Ni film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the Ni film on the back surface of the substrate (see FIG. 1).

### 4.1.5. Comparative Example 3

First, a 50 nm-thick SiC film (sputter-SiC) was formed as an adhesion layer on back surfaces of a GaN single crystal substrate and a sapphire substrate with a GaN film by a sputtering vapor deposition method.

Next, a spin-coated film of a photoresist (THMR-IP5700 manufactured by TOKYO OHKA KOGYO CO., LTD.) was formed so as to cover the SiC film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the SiC film on the back surface of the substrate (see FIG. 1).

### 4.1.6. Example 3

First, a 100 nm-thick Si film (EB-Si) was formed as an adhesion layer on back surfaces of a GaN single crystal substrate and a sapphire substrate with a GaN film by an electron-beam physical vapor deposition method.

Next, a spin-coated film of a photoresist (THMR-IP5700 manufactured by TOKYO OHKA KOGYO CO., LTD.) was formed so as to cover the Si film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the Si film on the back surface of the substrate.

Next, the carbon film and a 100 nm-thick expanded graphite sheet (PERMA-FOIR manufactured by Toyo Tanso Co., Ltd.) were adhered with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive.

Next, the substrate to which the expanded graphite sheet was joined was subjected to a heat treatment at a temperature of 800° C. for a time of 1 hour in a vacuum atmosphere to perform a carbonization treatment on the adhesive layer, thereby forming a joining layer (see FIG. 2).

### Examples 4 to 6 and Comparative Examples 4 to 6: Susceptor with Seed Crystal Substrate

### [4.2. Preparation of Sample]

### 4.2.1. Example 4

First, a seed crystal substrate was prepared in the same manner as in Example 1.

Next, the obtained seed crystal substrate and a graphite susceptor disposed on a back surface side of the seed crystal substrate were adhered with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive. The graphite susceptor was isotropic graphite.

Next, the graphite susceptor to which the seed crystal substrate was joined was subjected to a heat treatment at a temperature of 800° C. for a time of 1 hour in a vacuum atmosphere to perform a carbonization treatment on the adhesive layer, thereby forming a fixing layer (see FIG. 3).

Here, an average CTE of the graphite susceptor applied to the GaN single crystal substrate was 5.5×10⁻⁶ K⁻¹, and an average CTE of the graphite susceptor applied to the sapphire substrate with a GaN film was 7.1×10⁻⁶ K⁻¹.

### 4.2.2. Example 5

First, a seed crystal substrate was prepared in the same manner as in Example 1.

Next, a 100 nm-thick expanded graphite sheet (PERMA-FOIR manufactured by Toyo Tanso Co., Ltd.) was adhered to a surface of a graphite susceptor with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive. The graphite susceptor was isotropic graphite.

Next, the seed crystal substrate and a graphite susceptor disposed on a back surface side thereof were adhered with a phenol resin-based adhesive (ST-201 adhesive manufactured by Nisshinbo Chemical Inc.) via the expanded graphite sheet, and heated at a temperature of 200° C. for a time of 20 minutes in the atmospheric air to cure the phenol resin-based adhesive.

Next, the graphite susceptor joined with the seed crystal substrate was subjected to a heat treatment at a temperature of 800° C. for a time of 1 hour in a vacuum atmosphere to perform a carbonization treatment on the adhesive layer, thereby forming a joining layer and a fixing layer (see FIG. 4).

Here, an average CTE of the graphite susceptor applied to the GaN single crystal substrate was 5.5×10⁻⁶ K⁻¹, and an average CTE of the graphite susceptor applied to the sapphire substrate with a GaN film was 7.1×10⁻⁶ K⁻¹.

The expanded graphite sheet functions as a stress buffer layer.

### 4.2.3. Comparative Example 4

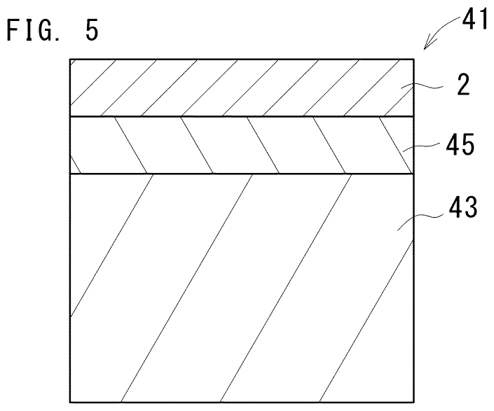

FIG. 5 shows a schematic cross-sectional view of susceptors with a seed crystal substrate according to Comparative Examples 4 and 5.

A graphite susceptor 41 with a seed crystal substrate includes:
the seed crystal substrate 2;
a graphite susceptor 43 disposed on a back surface side of the seed crystal substrate 2; and
a fixing layer 45 that fixes the substrate 2 to the graphite susceptor 43.

The substrate 2 is a GaN single crystal substrate or a sapphire substrate with a GaN film.

First, a GaN single crystal substrate and a sapphire substrate with a GaN film, and a graphite susceptor disposed on back surface sides of the respective substrates were adhered with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive. The graphite susceptor was isotropic graphite.

Next, the graphite susceptor to which the substrate was joined was subjected to a heat treatment at a temperature of 800° C. for a time of 1 hour in a vacuum atmosphere to perform a carbonization treatment on the adhesive layer, thereby forming a fixing layer (see FIG. 5).

Here, an average CTE of the graphite susceptor applied to the GaN single crystal substrate was 5.5×10⁻⁶ K⁻¹, and an average CTE of the graphite susceptor applied to the sapphire substrate with a GaN film was 7.1×10⁻⁶ K⁻¹.

### 4.2.4. Comparative Example 5

First, a GaN single crystal substrate and a sapphire substrate with a GaN film, and a graphite susceptor disposed on back surface sides of the respective substrates were adhered with a polycarbosilane-based adhesive (AD-478 manufactured by STARFIRE SYSTEMS), and heated at a temperature of 200° C. for a time of 20 minutes in the atmospheric air to cure the polycarbosilane-based adhesive. The graphite susceptor was isotropic graphite.

Next, the graphite susceptor to which the substrate was joined was subjected to a heat treatment at a temperature of 800° C. for a time of 1 hour in a vacuum atmosphere to perform a carbonization treatment on the adhesive layer, thereby forming a fixing layer (see FIG. 5).

Here, an average CTE of the graphite susceptor applied to the GaN single crystal substrate was 5.5×10⁻⁶ K⁻¹, and an average CTE of the graphite susceptor applied to the sapphire substrate with a GaN film was 7.1×10⁻⁶ K⁻¹.

### 4.2.5. Comparative Example 6

First, a seed crystal substrate was prepared in the same manner as in Example 1.

Next, the obtained seed crystal substrate and a graphite susceptor disposed on a back surface side of the seed crystal substrate were adhered with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive. The graphite susceptor was isotropic graphite.

Next, the graphite susceptor to which the seed crystal substrate was joined was subjected to a heat treatment at a temperature of 800° C. for a time of 1 hour in a vacuum atmosphere to perform a carbonization treatment on the adhesive layer, thereby forming a fixing layer.

Here, an average CTE of the graphite susceptor applied to the GaN single crystal substrate was 4.8×10⁻⁶ K⁻¹, and an average CTE of the graphite susceptor applied to the sapphire substrate with a GaN film was 5.5×10⁻⁶ K⁻¹.

### 4.2.6. Example 6

First, a seed crystal substrate was prepared in the same manner as in Example 1.

Next, a 100 nm-thick expanded graphite sheet (PERMA-FOIR manufactured by Toyo Tanso Co., Ltd.) was adhered to a surface of a graphite susceptor with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive. The graphite susceptor was isotropic graphite.

Next, the seed crystal substrate and a graphite susceptor disposed on a back surface side thereof were adhered with a phenol resin-based adhesive (ST-201 adhesive manufactured by Nisshinbo Chemical Inc.) via the expanded graphite sheet, and heated at a temperature of 200° C. for a time of 20 minutes in the atmospheric air to cure the phenol resin-based adhesive.

Next, the graphite susceptor joined with the seed crystal substrate was subjected to a heat treatment at a temperature of 800° C. for a time of 1 hour in a vacuum atmosphere to perform a carbonization treatment on the adhesive layer, thereby forming a joining layer and a fixing layer.

Here, an average CTE of the graphite susceptor applied to the GaN single crystal substrate was 4.8×10⁻⁶ K⁻¹, and an average CTE of the graphite susceptor applied to the sapphire substrate with a GaN film was 5.5×10⁻⁶ K⁻¹.

The expanded graphite sheet functions as a stress buffer layer.

### [4.3. Test Method]

### [4.3.1. Adhesion Test (Examples 1 and 2 and Comparative Examples 1 to 3)]

Adhesion of a laminate of an adhesion layer and a carbon film which were formed on the back surface of the substrate was evaluated by tape peeling (tape test JIS H8504). A case where the carbon film or the like attached to the peeled-off tape surface was determined as poor (x), and a case where the carbon film or the like did not attach to the peeled-off tape surface was determined as good (o).

### [4.3.2. Joinability Test (Examples 3 to 6 and Comparative Examples 4 to 6)]

The joint state of the joining layer or the fixing layer was evaluated. The joint state was evaluated by visual observation from the substrate surface. A case where good joint was obtained in 80% or more of the joint area was determined as good (o). A case where good joint was obtained in 30% or more and less than 80% of the joint area was determined as partially good (Δ). A case where good joint was obtained in only less than 30% of the joint area was determined as poor (x).

Since the adhesion layer and the carbon film are thin, the joint state of the joining layer or the fixing layer can be visually confirmed from the substrate surface.

### [4.3.3. Crystal Growth Test (Examples 1 to 6 and Comparative Example 5)]

GaN single crystal growth was performed by an HF-VPE method to evaluate crystallinity. The surface morphology after crystal growth was observed with a microscope to identify whether the crystals were single crystals or polycrystals from the symmetry of the morphology. A case of single crystals was evaluated as good (o), a case of polycrystals was evaluated as poor (x), and a case where the growth of single crystals was partially observed was evaluated as partially good (Δ).

### [4.4. Results]

The results are shown in Table 1. The following matters are seen from Table 1.

It was found that all of Comparative Examples 1 to 3 showed poor adhesion of the adhesion layer to the GaN single crystal substrate and the sapphire substrate.

Note that Ti, Ni, and SiC, which are materials used for the adhesion layer in Comparative Examples 1 to 3, do not disappear at the GaN single crystal growth temperature (≈1100° C.), and that their good adhesion to the carbon film was also taken into consideration.

In addition, in the crystal growth test in Examples 1 to 3, the seed crystal substrate was subjected to GaN single crystal growth in a state where the seed crystal substrate was held in the HF-VPE apparatus by a grip holding a peripheral edge thereof. That is, GaN single crystal growth was performed in a state where the seed crystal substrate was present alone without using a graphite susceptor or the like.

The results of Examples 4 and 5 revealed that both the examples showed good crystal growth test results, but that the joinability of the joining layer or the fixing layer was better when the expanded graphite sheet as the stress buffer layer was interposed and inserted between the seed crystal substrate and the graphite susceptor. Therefore, in the crystal growth over a long time, it is more preferable to interpose and insert the expanded graphite sheet as the stress buffer layer.

From the results of Comparative Example 4, it was confirmed that the adhesiveness of the carbon-based adhesive to the GaN single crystal substrate and the sapphire substrate was poor as described above.

Also, from the results of Comparative Example 5, the sapphire substrate and the GaN single crystal substrate could be joined to the graphite susceptor by using the polycarbosilane-based adhesive. However, it could be confirmed that, as described above, the polycarbosilane-based adhesive generated Si-containing gas molecular species during growth of GaN single crystals, which attached to GaN seed crystal surfaces as Si impurities and inhibited growth of high-quality GaN single crystals.

The results of Comparative Example 6 revealed that matching in average CTE between the substrate and the graphite susceptor was important. Insufficient matching in average CTE between the substrate and the graphite susceptor results in a possibility that the seed crystal substrate falls off from the graphite susceptor during heating and temperature rise.

From the results of Example 6, it could be confirmed that even in the case where the matching in average CTE between the substrate and the graphite susceptor was insufficient, the expanded graphite sheet, when provided, functioned as the stress buffer layer. In combination with the results of Example 5, the graphite susceptor with a seed crystal substrate preferably includes an expanded graphite sheet as the stress buffer layer.

TABLE 1

| | Substrate | Adhesion layer | Carbon film | Adhesive |
|---|---|---|---|---|
| Example1 | GaN | EB-Si: 100 nm | Resist Carbonized film: 20 nm | — |
| | GaN/Sapphire | EB-Si: 100 nm | Resist Carbonized film: 20 nm | — |
| Example2 | GaN | Sputter-Si: 50 nm | Resist Carbonized film: 20 nm | — |
| | GaN/Sapphire | Sputter-Si: 50 nm | Resist Carbonized film: 20 nm | — |
| Comparative | GaN | EB-Ti: 100 nm | Resist Carbonized film: 20 nm | — |
| Example1 | GaN/Sapphire | EB-Ti: 100 nm | Resist Carbonized film: 20 nm | — |
| Comparative | GaN | EB-Ni: 100 nm | Resist Carbonized film: 20 nm | — |
| Example2 | GaN/Sapphire | EB-Ni: 100 nm | Resist Carbonized film: 20 nm | — |
| Comparative | GaN | Sputter-SiC: 50 nm | Resist Carbonized film: 20 nm | — |
| Example3 | GaN/Sapphire | Sputter-Si: C50 nm | Resist Carbonized film: 20 nm | — |
| Example3 | GaN | EB-Si: 100 nm | Resist Carbonized film: 20 nm | Phenol resin-based |
| | GaN/Sapphire | EB-Si: 100 nm | Resist Carbonized film: 20 nm | Phenol resin-based |
| Example4 | GaN | EB-Si: 100 nm | Resist Carbonized film: 20 nm | Phenol resin-based |
| | GaN/Sapphire | EB-Si: 100 nm | Resist Carbonized film: 20 nm | Phenol resin-based |
| Example5 | GaN | EB-Si: 100 nm | Resist Carbonized film: 20 nm | Phenol resin-based |
| | GaN/Sapphire | EB-Si: 100 nm | Resist Carbonized film: 20 nm | Phenol resin-based |
| Comparative | GaN | — | — | Phenol resin-based |
| Example4 | GaN/Sapphire | — | — | Phenol resin-based |
| Comparative | GaN | — | — | Polycarbosilane-based |
| Example5 | GaN/Sapphire | — | — | Polycarbosilane-based |
| Comparative | GaN | EB-Si: 100 nm | Resist Carbonized film: 20 nm | Phenol resin-based |
| Example6 | GaN/Sapphire | EB-Si: 100 nm | Resist Carbonized film: 20 nm | Phenol resin-based |
| Example5 | GaN | EB-Si: 100 nm | Resist Carbonized film: 20 nm | Phenol resin-based |
| | GaN/Sapphire | EB-Si: 100 nm | Resist Carbonized film: 20 nm | Phenol resin-based |

| | | Coefficient | | | |
|---|---|---|---|---|---|
| | | of thermal | | | |
| | Radiation | expansion of | | | Crystal |
| | Enhancement layer/ | graphite | Adhesion | Joinability | growth |
| | Stress buffer layer | susceptor | test | test | test |
| Example1 | — | — | ◯ | — | ◯ |
| | — | — | ◯ | — | ◯ |
| Example2 | — | — | ◯ | — | ◯ |
| | — | — | ◯ | — | ◯ |
| Comparative | — | — | X | — | — |
| Example1 | — | — | X | — | — |
| Comparative | — | — | X | — | — |
| Example2 | — | — | X | — | — |
| Comparative | — | — | X | — | — |
| Example3 | — | — | X | — | — |
| Example3 | Expanded graphite: 100 μm | — | — | ◯ | ◯ |
| | Expanded graphite: 100 μm | — | — | ◯ | ◯ |
| Example4 | — | 5.5 × 10⁻⁶K⁻¹ | — | Δ | ◯ |
| | — | 7.1 × 10⁻⁶K⁻¹ | — | Δ | ◯ |
| Example5 | Expanded graphite: 100 μm | 5.5 × 10⁻³K⁻¹ | — | ◯ | ◯ |
| | Expanded graphite: 100 μm | 7.1 × 10⁻³K⁻¹ | — | ◯ | ◯ |
| Comparative | — | 5.5 × 10⁻⁵K⁻¹ | — | X | — |
| Example4 | — | 7.1 × 10⁻⁵K⁻¹ | — | X | — |
| Comparative | — | 5.5 × 10⁻⁶K⁻¹ | — | ◯ | X |
| Example5 | — | 7.1 × 10⁻⁶K⁻¹ | — | ◯ | X |
| Comparative | — | 4.8 × 10⁻⁶K⁻¹ | — | X | — |
| Example6 | — | 5.5 × 10⁻⁶K⁻¹ | — | X | — |
| Example5 | Expanded graphite: 100 μm | 4.8 × 10⁻⁵K⁻¹ | — | Δ | Δ |
| | Expanded graphite: 100 μm | 5.5 × 10⁻⁵K⁻¹ | — | Δ | Δ |

### Example 7, Influence of Thickness of Adhesion Layer on Joinability

### [4.5. Preparation of Sample]

First, 0, 10, 50, 100, 200, and 500 nm-thick Si films were formed as adhesion layers on back surfaces of a GaN single crystal substrate and a sapphire substrate with a GaN film by an electron beam vapor deposition method.

Next, a spin-coated film of a photoresist (THMR-IP5700 manufactured by TOKYO OHKA KOGYO CO., LTD.) was formed so as to cover the Si film. The rotation rate in spin coating was 5000 rpm, and the time was 30 seconds.

Next, the substrate with the spin-coated film was subjected to a heat treatment at a temperature of 800° C. for a time of 1 hour in a vacuum atmosphere to carbonize the spin-coated film, thereby forming a 20 nm-thick carbon film covering the Si film on the back surface of the substrate.

Next, a 100 μm-thick expanded graphite sheet (PERMA-FOIR manufactured by Toyo Tanso Co., Ltd.) was adhered to a surface of a graphite susceptor with a phenol resin-based adhesive (ST-201 adhesive manufactured by Nisshinbo Chemical Inc.), and heated at a temperature of 200° C. for a time of 20 minutes in the atmospheric air to cure the phenol resin-based adhesive. The graphite susceptor was isotropic graphite.

Next, the seed crystal substrate and a graphite susceptor disposed on a back surface side thereof were adhered with a phenol resin-based adhesive (ST-201 adhesive manufactured by Nisshinbo Chemical Inc.) via the expanded graphite sheet, and heated at a temperature of 200° C. for a time of 20 minutes in the atmospheric air to cure the phenol resin-based adhesive.

Next, the graphite susceptor joined with the seed crystal substrate was subjected to a heat treatment at a temperature of 800° C. for a time of 1 hour in a vacuum atmosphere to perform a carbonization treatment on the adhesive layer, thereby forming a joining layer and a fixing layer.

Then, a joinability test of the joining layer was performed visually.

### [4.6. Results]

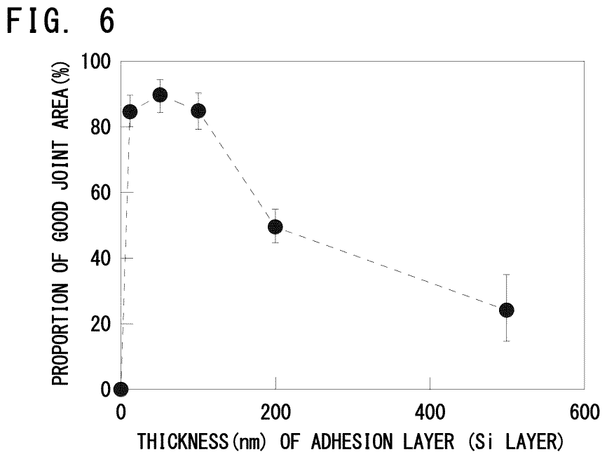

The results are shown in FIG. 6. The following matters are seen from FIG. 6.

(1) When the thickness of the adhesion layer was 200 nm or less, the portion with good joint accounted for 50% or more.

(2) When the thickness of the adhesion layer was in a range of 10 nm to 100 nm, the portion with good joint accounted for 80% or more.

(3) When the thickness of the adhesion layer was less than 10 nm, the rate of change in portion with good joint to the film thickness was steep.

Therefore, in the range where the thickness of the adhesion layer is less than 10 nm, there is a possibility that the portion with good joint greatly changes even with a minute change in thickness of the adhesion layer, and it cannot be said that this range is suitable for use.

In addition, when the thickness of the adhesion layer exceeds 200 nm, the portion with good joint accounts for less than half.

Therefore, it has been found that a suitable range of the thickness of the adhesion layer is 10 nm or more and 200 nm or less.

Although the embodiments of the present invention have been described in detail above, the present invention is not limited to the above embodiments at all, and various modifications can be made without departing from the gist of the present invention.

The seed crystal substrate and the graphite susceptor with a seed crystal substrate according to the present invention can be used when a GaN single crystal is subjected to vapor phase growth.

1. A seed crystal substrate comprising:
a substrate having a GaN seed crystal on a front surface thereof;
an adhesion layer formed on a back surface of the substrate; and
a carbon film covering the adhesion layer,
wherein
the substrate includes a GaN single crystal substrate or a sapphire substrate with a GaN film, and
the adhesion layer contains Si.

2. The seed crystal substrate according to claim 1, wherein the adhesion layer has a thickness of 10 nm or more and 200 nm or less.

3. The seed crystal substrate according to claim 1, wherein the carbon film has a thickness of 5 nm or more and 100 nm or less.

4. The seed crystal substrate according to claim 1, further comprising:
an expanded graphite sheet disposed on a back surface side of the carbon film; and
a joining layer that joins the carbon film and the expanded graphite sheet.

5. The seed crystal substrate according to claim 4, wherein the joining layer comprises:
graphite particles; and
a carbon layer interposed between the graphite particles.

6. A graphite susceptor with a seed crystal substrate, comprising:
the seed crystal substrate according to claim 1;
a graphite susceptor disposed on a back surface side of the seed crystal substrate; and
a fixing layer that fixes the seed crystal substrate to the graphite susceptor,
wherein an absolute value of a difference in average coefficient of thermal expansion between the substrate and the graphite susceptor is 0.5×10⁻⁶ K⁻¹ or less.

7. The graphite susceptor with a seed crystal substrate according to claim 6, wherein the fixing layer comprises:
graphite particles; and
a carbon layer interposed between the graphite particles.

8. A graphite susceptor with a seed crystal substrate, comprising:
the seed crystal substrate according to claim 4;
a graphite susceptor disposed on a back surface side of the seed crystal substrate; and
a fixing layer that fixes the seed crystal substrate to the graphite susceptor.

9. The graphite susceptor with a seed crystal substrate according to claim 8, wherein an absolute value of a difference in average coefficient of thermal expansion between the substrate and the graphite susceptor is 0.5×10⁻⁶ K⁻¹ or less.

10. The graphite susceptor with a seed crystal substrate according to claim 8, wherein the fixing layer comprises:
graphite particles; and
a carbon layer interposed between the graphite particles.
